(19) United States
(12) Patent Application Publication
(10) Pub. No.: US 2004/0158794 A1
(43) Pub. Date: Aug. 12, 2004

(54) Reduced overhead CRC functionality for packets and link layer superframes

(76) Inventor: Joseph W. Niesen, Yorba Linda, CA (US)

Correspondence Address: HARNESS, DICKEY & PIERCE, P.L.C., P.O. BOX 828, BLOOMFIELD HILLS, MI, 48303, US

(21) Appl. No.: 10/774,010

(22) Filed: Feb. 6, 2004

Related U.S. Application Data
(63) Continuation-in-part of application No. 10/623,475, filed on Jul. 18, 2003.
(60) Provisional application No. 60/397,226, filed on Jul. 19, 2002.

(51) Int. Cl. H03M 13/00

(52) U.S. Cl. 714/758

(57) ABSTRACT

An improved method for performing cyclic redundancy check (CRC). The present invention condenses a plurality of CRC sequences into a single reduced bit count CRC equivalent. The number of bits occupied by the reduced bit count CRC equivalent is fewer than the number of bits occupied by the individual CRC sequences. Thus, the present invention reduces the number of bits required to perform the CRC operation, thereby increasing the number of bits available for transporting information data bits.

### CROSS-REFERENCE TO RELATED APPLICATIONS

This application is a continuation-in-part of U.S. patent application Ser. No. 10/623,475 filed on Jul. 18, 2003, which claims the benefit of U.S. Provisional Application No. 60/397,226, filed on Jul. 19, 2002. The disclosures of the above applications are incorporated herein by reference.

### FIELD OF THE INVENTION

The present invention generally relates to the fields of data processing and data communications. More specifically, the present invention relates to the use of cyclic redundancy check to detect data transmission errors and the reduction of the number of bits used by cyclic redundancy check to detect such errors.

### BACKGROUND OF THE INVENTION

Depending on the medium by which data is transferred, data errors may occur during transmission. In many applications it is important to know whether the data received is identical to the data transmitted or whether errors did in fact occur during transmission. Cyclic redundancy check (CRC) is a widely used technique to determine whether data received is identical to data transmitted and is thus accurate and reliable for use.

CRC is specifically used to verify the reliability of information data bits packaged and transmitted in payload packets. The information data bits are data bits that encode information that is directly used by the end user. Using CRC, the transmitter adds an extra n-bit sequence to every packet, called a check sequence. The check sequence stores redundant information about the packet so as to aid the detection of errors within the packet after transmission. However, the check sequence also occupies a number of valuable bits that could otherwise be used as information data bits. Multiple packets, each having individual check sequences, may be transmitted within a single structure called a superframe. Within the superframe, the individual packets and their associated check sequences are divided by flags and the particulars of the superframe are provided within a region known as the superframe overhead.

CRC functions by performing a mathematical calculation on each data packet to generate a number representing the content and organization of the data within the associated packet. The number generated serves as a unique identifier or “fingerprint” of the associated data and is generally referred to as a “checksum.” By comparing a checksum associated with one data packet with a checksum associated with a different data packet, a determination can be made as to whether the data blocks are identical or not. The advantage of CRC is that it is virtually impossible for a random change in a data packet to generate the same checksum. The length of the check sequence is balanced against the max length of the packet so that the probability that a random sequence of errors within the packet information bits will not result in a change in the check sequence is extremely low. For example, for a 10E⁻⁵ bit error rate channel the probability of an error going undetected using CRC32C is 10E⁻²⁰ as reported by Guy Castagnoli et al. See Guy Castagnoli, Stefan Braeuer and Martin Herrman “Optimization of Cyclic Redundancy-Check Codes with 24 and 32 Parity Bits”, IEEE Transact. On Communications, Vol. 41, No. 6, June 1993.

With Internet IP protocols, if CRC determines that the transmitted packet is corrupted, the action taken depends on the particular protocol used. If TCP is used, the packet will be retransmitted. If UDP is used, CRC will identify the corrupted packets and the higher OSI layer protocols will then decide whether to either discard the corrupted packets or apply special processing to the packets.

CRC sequences typically occupy either 12 bits, 16 bits, or 32 bits of a particular packet. If a 16 bit CRC sequence is used the packet is limited to 4096 bits in length. If a 32 bit CRC sequence is used the packet is limited to 16 kbyte in length. As superframe packets are limited in length, the number of bits available for storing and transporting information data bits is also limited. Thus, every bit used by the CRC sequence is one less bit available for use as an information data bit.

Reduction of the number of bits used by the CRC sequences is desirable because it increases the number of bits available for use in the storage and transport of information data bits. Reduction of the bits used by the CRC sequences would be particularly useful in limited bandwidth satellite and wireless links to improve throughput. Consequently, there is a need for a CRC technique in which the CRC sequences occupy a number of bits that is less than the number occupied by current CRC techniques.

### SUMMARY OF THE INVENTION

The present invention overcomes the deficiencies of the prior art by providing a CRC technique in which the number of bits required by CRC sequences is reduced, thus increasing the number of bits available for the storage and transport of information data bits within the superframe. Specifically, the present invention condenses a plurality of CRC sequences into a single reduced bit count CRC equivalent. The number of bits occupied by the reduced bit count CRC equivalent is fewer than the number of bits occupied by the individual CRC sequences, thus freeing additional bits within the superframe packets for use in the storage and transportation of information data bits.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 illustrates the construction of a reduced bit count superframe structure in accordance with a preferred embodiment of the present invention;

FIG. 2 illustrates numerous different error detection codes that may be used to process data packets of the present invention and various different properties associated with each error detection code; and

FIG. 3 illustrates a received reduced bit count superframe structure and the processing of the received reduced bit count superframe structure so as to detect and correct data transmission errors.

### DETAILED DESCRIPTION OF THE PREFERRED EMBODIMENTS

The following description of the preferred embodiments is merely exemplary in nature and is in no way intended to limit the invention, its application, or uses.

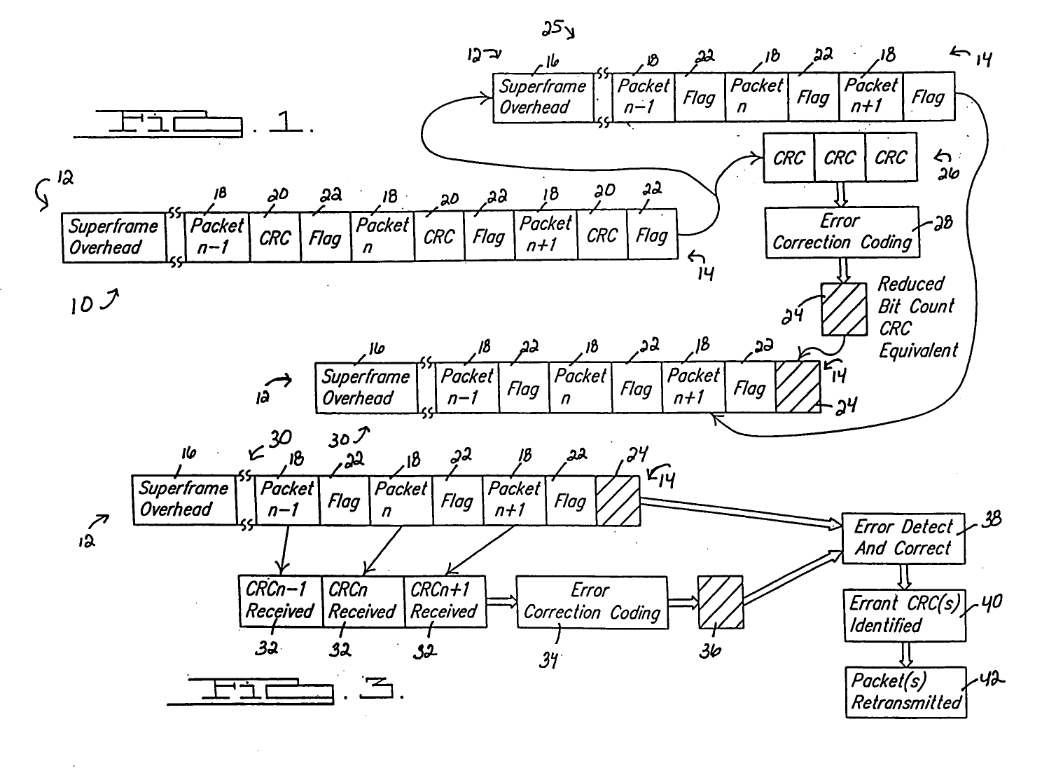

FIG. 1 illustrates a link layer superframe structure at 10. The superframe 10 may be used with a variety of different applications, but is commonly used with data links having large time bandwith products and for data links that require superframes for timing estimation. The superframe structure 10 uses cyclic redundancy check (CRC) to ensure that the data carried by superframe 10 at the time of transmission is identical to the data carried by superframe 10 upon reception. The superframe 10 has an upstream end 12 and a downstream end 14. The superframe 10 is comprised of numerous different regions, such as superframe overhead region 16 located at the upstream end 12. Superframe overhead region 16 contains general data concerning the superframe 10, such as, but not limited to, the overall length of superframe 10, the beginning and ending points of superframe 10, and the type of information carried by superframe 10.

Superframe 10 also contains a plurality of payload packets 18. The packets 18 encode information data bits, which are data bits having information that is directly used by the end user. Each packet 18 contains a CRC sequence 20 located at the downstream end 14 of each packet 18. The CRC sequence 20 produces a checksum that is the result of a mathematical calculation performed on the associated packet 18. The checksum represents the content and organization of the data within the associated packet 18. The size of the CRC sequence 20 varies depending on the size of the packet 18. For example, if packet 18 is less than 4096 bits in length then the CRC sequence 20 will have 16 bits. If the packet 18 is between 4096 and 16 kbyte bits in length then the CRC sequence 20 will have 32 bits.

Superframe 10 is further comprised of one or more flags 22. Flags 22 encode information indicating where each packet 18 begins and where each packet 18 ends. Thus, flags 22 define the boundaries between different packets 18.

The present invention condenses the different check sequences 20 into a single reduced bit count CRC sequence equivalent 24. The reduced bit count CRC equivalent 24 occupies fewer bits than the combined multiple check sequences 20. Thus, because the total number of bits within packets 18 and superframe 10 is limited, the present invention increases the number of bits available to packet 18 for the storage and transmission of information data bits by reducing the number of bits needed for CRC. While the current invention is generally described in terms of packets 18 organized in superframe 30, it must be realized that the invention may be used to condense the check sequences 20 of packets 18 that are independent of superframe 30 as single packets 18 or multiple grouped packets 18.

Before condensing check sequences 20, the check sequences 20 must be located. Because flags 22 indicate the location of the different packets 18 and because the size of the check sequences 20 is known, the position of the check sequences 20 for each packet 18 may be located by counting the bits in reverse from the location of the flags 22. After the CRC sequences 20 are located, the check sequences 20 are removed from superframe 10, resulting in both an abbreviated superframe 25 without CRC sequences 20 and a series of independent check sequences 26.

The series of independent check sequences 26 are processed by an correction code 28, such as a forward correction code, common forward error correction codes that may be used include block codes, convolutional codes, turbo product (block) codes, and turbo convolutional codes. Block codes that may be used include Hamming codes and BCH codes. The error correction code 28 reduces the independent CRC sequences 26 into the single reduced bit count CRC sequence equivalent 24. Further, the error correction code 28 ensures that the reduced bit count check sequence 24 is an accurate representation of the individual CRC sequences 26.

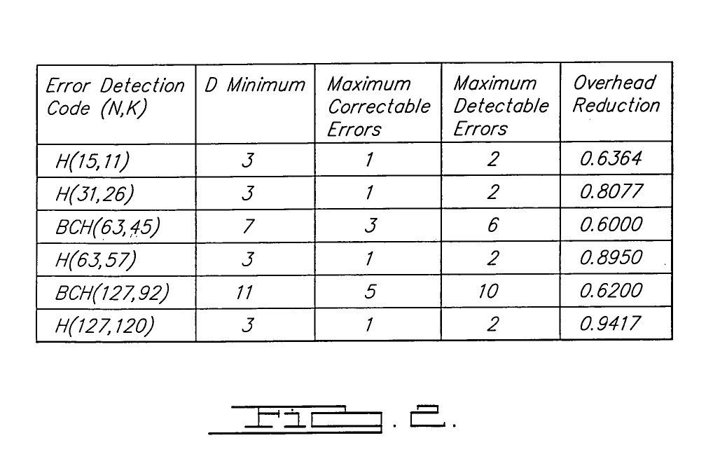

When the error correction code 28 is applied to the check sequence 20 of a single packet 18 apart from superframe 12, the functional responsibility of the error correction code 28 is only to detect and not to correct errors. Detection of an error in check sequence 20 means that the packet 18 involved with the check sequence 20 has been corrupted and must be discarded. As illustrated in FIG. 2, error correction codes 28 have stronger error detection performance than they do error correction performance.

In FIG. 2, the error detection codes take the form code type (N,K), where K bits are input to the code and N bits are output from the code. The first K bits of the output are identical to the K bit code input, and the remaining N-K bits are the parity bits generated and output by the error correction code. As described more fully below, in the present invention N-K (check) parity bits of the check sequences 20 are transmitted in place of the check sequences 20. Lossless coding, such as by Huffman coding, arithmetic coding, or Lempel-Ziv coding; bit padding; and/or processing of the check sequences 20 from multiple packets may be used to match the block error coding input (K) to the length of check sequence 20.

When the error correction code 28 is applied to check sequences 20 from multiple packets forming superframe 12, the functional responsibility of the error correction code 28 is to correct errors in the check sequence 20. The event of error locating in multiple check sequences 20 points to which check sequence 20 has been corrupted and which packet 18 must be discarded. Again, the error correction capabilities of select error correction codes are illustrated in FIG. 2. In addition to the codes of FIG. 2, additional block turbo codes and convolutional codes for forward error correction (FEC), as are known in the art, may be used.

Usage of multiple packet check sequences 20 or single packet check sequences 20 depends on the packet error rate and bit error rate of the communication channel. The reduced bit check sequences 20 must operate in a mode to meet or exceed the ability of the check sequence 20 to detect corrupted information bits in the packet 18.

The reduced bit count check sequence 24 may be from approximately 1/20 to approximately 1/2 the length of the individual CRC sequences 20. For example, if packet 18 is a minimum length 38 byte Ethernet packet, the overhead associated with a 2 byte (16 bit) CRC is reduced from approximately 5% to approximately 0.2%. Further, for a 1.5 Mbps return link, about 75 kbps of bandwidth are freed for use in data transmission. As the size of the reduced bit check sequence 24 is increased, more data bits become available within the packets 18. The reduction of the size of the CRCs 20 for forward error correction (FEC) is q CRC bits divided by r FEC redundancy bits. Normally, the code rate for an FEC code is: q/(q+r). The number of CRC bits 20 transmitted is reduced because the q CRC bits 20 normally transmitted are replaced by the r redundancy bits that result from using the FEC operation on the CRC bits.

After the reduced bit count check sequence 24 is obtained, it is added to the downstream terminus 14 of abbreviated superframe 25 to form a reduced bit count CRC superframe 30. Once formed, the reduced bit count CRC superframe 30 may be transmitted through any suitable medium by any suitable transmitter.

The transmitted reduced bit count CRC superframe 30 may be received using any suitable receptor. Once received, the transmitted packets 18 of the reduced bit count CRC superframe 30 are checked to determine whether the data encoded within packets 18 as received is identical to the data of packets 18 as transmitted (FIG. 3).

To determine whether the data of the packets 18 of the reduced bit count CRC superframe 30 as received is identical, or substantially identical, to data of the packets 18 as transmitted, CRC is performed for each received packet 18 so as to obtain received CRC sequences 32 that correspond to each received packet 18. The CRC sequences 32 of the received packets 18 are then processed using an error correction code 34. The error correction code 34 may be any suitable error correction code, such as a forward correction code. The forward correction codes that may be used are similar to those that may be used with correction code 28. The error correction code 34 reduces the individual received CRC sequences 32 into a single reduced bit count received CRC sequence 36. Further, the error correction code 34 ensures that the reduced bit count received CRC sequence 36 is an accurate representation of the individual received CRC sequences 32. As discussed above, the error correction code 34 may process packets 18 that are independent or organized into superframes 12.

The reduced bit count received CRC sequence 36 is compared to the reduced bit count CRC sequence 24 at 38. If the checksums of the reduced check sequences 24, 36 are the same then the packets 18 were received in the same condition as transmitted. If the checksums are different, then an error occurred during transmission. After an error is detected at 38, the location of the error is determined at 40 using standard CRC techniques.

The forward error correction code (FEC) used on a single or grouped set of CRC's should correct at least one bit error (of possibly many that occur) in each single CRC. The implication here is that if an error is corrected, the bit position in the string of CRC's has been identified. If the bit position is identified, then the related CRC has detected corruption of its associated packet. Further, the number of bit changes in a CRC should not exceed the FEC's ability to correct at least one error. If the received CRC has bit changes that move it to one of the accepted bit sequences of the FEC, no errors will be detected/corrected by the FEC.

Once located, the packet(s) 18 having errors are discarded and, depending upon the application, a request may be made to retransmit the corrupt packets(s) 18 at 42. A superframe 10 comprised of the packets 18 that were previously transmitted in error may then be constructed and again transmitted using the above described procedure to determine whether the received packets 18 contain errors.

In some applications, the particular IP protocol used in a given application has a bearing on whether or not the corrupted packet is retransmitted. For example, if TCP is used the corrupt packet will be retransmitted. Alternatively, if UDP is used, the corrupt packet will not necessarily be re-transmitted, but rather the corrupt packet is identified by CRC so that higher OSI layer protocols can decide how to process the corrupt packet.

Under physical layer operation with high bit error rate, there may be situations where the bit errors make a pattern within the CRC that is not detected by the proposed method. Operation in such high bit error rate situation is typically precluded by modern communication control systems of the physical layer, which reduce data rate or increase transmit power in order to move from the high bit error rate operation to low bit error rate operation. In addition, CRC error correcting or error detecting codes can be designed and chosen to deal specially with high bit error rate operation, in the event current state-of-the-art physical layer communication control systems are not used.

As described above, a method for detecting data transmission errors using cyclic redundancy check (CRC) is provided. The present invention condenses a plurality of CRC sequences 20 into a single reduced bit count CRC equivalent 24. The number of bits occupied by the reduced bit count CRC equivalent 24 is fewer than the number of bits occupied by the individual CRC sequences 20. Thus, the present invention reduces the number of bits required to perform the CRC operation, thereby increasing the number of bits available for transporting information data bits.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A method for verifying the validity of transmitted digital information data bits arranged in one or more data packets comprising:
performing a cyclic redundancy check on said one or more data packets to obtain a check sequence for each said one or more data packets; and
condensing said check sequences into a single reduced bit count check sequence equivalent; and
wherein the number of bits occupied by said reduced bit count check sequence equivalent is fewer than the number of bits occupied by said check sequences, thus freeing additional data bits for use by digital information data bits.

2. The method of claim 1, further comprising:
transmitting said reduced bit count check sequence equivalent and said data packets;
receiving said reduced bit count check sequence equivalent and said data packets;
performing said cyclic redundancy check on said received data packets to obtain received check sequences;
condensing said received check sequences into a single reduced bit count received check sequence; and
comparing said reduced bit count received check sequence with said reduced bit count transmitted check sequence to determine if said data packets were transmitted accurately.

3. The method of claim 2, further comprising:
retransmitting any of said data packets transmitted with errors.

4. The method of claim 1, wherein said condensing step is performed by an error correction code.

5. The method of claim 1, wherein said data packets comprise multiple data packets within a superframe.

6. The method of claim 1, wherein said data packets comprise stand-alone data packets.

7. The method of claim 1, wherein said data packets comprise multiple data packets.

8. A data transmission system comprising:
a transmitter operable to perform a cyclic redundancy check on at least one data packet to produce at least one check sequence representing said data packet; and
a condensing device operable to condense said at least one check sequence into a check sequence equivalent that is smaller than said at least one check sequence; and
wherein said at least one data packet and said check sequence equivalent are transmitted by said transmitter.

9. The system of claim 8, wherein the number of bits occupied by said check sequence equivalent is fewer than a number of bits occupied by said at least one check sequence, thus freeing additional data bits for use as information data bits.

10. The system of claim 8, further comprising:
a receiving device operable to receive said transmitted data packet and said transmitted check sequence equivalent and operable to perform cyclic redundancy check on said transmitted data packet.

11. The system of claim 10, wherein said receiving device further comprises:
a forward error correction code device operable to reduce said transmitted data packets into a single reduced bit count received cyclic redundancy check sequence.

12. The system of claim 11, further comprising:
a comparator for comparing said reduced bit count received cyclic redundancy check sequence with said reduced bit count transmitted cyclic redundancy check sequence to determine whether said at least one data packet was received by said receiver in substantially the same condition as transmitted by said transmitter.

13. The system of claim 8, wherein said condensing device comprises a forward error correction code.

14. The system of claim 11, wherein said forward error correction code device comprises a block code.

15. The system of claim 8, wherein said at least one data packet comprises a plurality of data packets associated with a single superframe.

16. The system of claim 11, wherein said data packets that are received by said receiver in a condition different then transmitted by said transmitter are re-transmitted from said transmitter to said receiver.

17. A method for verifying the validity of transmitted digital information data bits arranged in one or more data packets comprising:
performing a cyclic redundancy check on said one or more data packets to obtain a check sequence for each said one or more data packets;
condensing said check sequences into a single reduced bit count check sequence equivalent, wherein the number of bits occupied by said reduced bit count check sequence equivalent is fewer than the number of bits occupied by said check sequences, thus freeing additional bits for use as information data bits;
transmitting said reduced bit count check sequence equivalent and said data packets;
receiving said reduced bit count check sequence equivalent and said data packets;
performing said cyclic redundancy check on said received data packets to obtain received check sequences;
condensing said received check sequences into a single reduced bit count received check sequence; and
comparing said reduced bit count received check sequence with said reduced bit count transmitted check sequence to determine if said data packets were transmitted accurately.

18. The method of claim 17, wherein both of said condensing steps are performed by a forward error correction code.

19. The method of claim 17, wherein said data packets comprise a superframe.

20. The method of claim 19, further comprising:
retransmitting any of said data packets transmitted with errors.

21. The method of claim 19, further comprising:
Identifying said data packets that are transmitted with errors so that said data packets with errors can be further processed.
